(19) United States
(12) Patent Application Publication
(10) Pub. No.: US 2025/0329569 A1
(43) Pub. Date: Oct. 23, 2025

(54) SUBSTRATE HOLDING SYSTEM AND LITHOGRAPHIC APPARATUS

(71) Applicant: ASML NETHERLANDS B.V., Veldhoven (NL)

(72) Inventors: Diego MILLO, Amsterdam (NL); Dennis Domicnic VAN DER VOORT, Best (NL)

(73) Assignee: ASML NETHERLANDS B.V., Veldhoven (NL)

(21) Appl. No.: 18/866,780

(22) PCT Filed: May 23, 2023
(86) PCT No.: PCT/EP2023/063752

§ 371 Date: Nov. 18, 2024

(30) Foreign Application Priority Data
Jul. 7, 2022 (EP) 22183530.9

(51) Int. Cl. H01L 21/683; H01L 21/67

(52) U.S. Cl. CPC H01L 21/6838; H01L 21/67017

(57) ABSTRACT

A substrate holding system includes a substrate support configured to support a substrate, a gas source, and a plurality of conduits. The substrate support includes a first port and a plurality of second ports radially outwards of the first port. The first port and the plurality of second ports are configured to be in fluid communication with the gas source. The gas source is configured to supply an inert gas to a region between the substrate and the substrate support via the first port and the plurality of second ports. The substrate holding system is configured such that the inert gas can be supplied to the region between the substrate and the substrate support through the first port or the plurality of second ports. The substrate holding system is configured to extract gas from the region between the substrate and the substrate support through the plurality of second ports.

### CROSS-REFERENCE TO RELATED APPLICATIONS

This application claims priority of EP application 22183530.9 which was filed on Jul. 7, 2022 and which is incorporated herein in its entirety by reference.

### FIELD

The present invention relates to a substrate holding system, a lithographic apparatus including a substrate holding system, a method of supporting a substrate on a substrate support, and a method of manufacturing a device including a method of supporting a substrate on a substrate support.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

### SUMMARY

In a semiconductor manufacturing process, a substrate is supported on a substrate support. Specifically, the substrate is supported on a plurality of burls protruding from the a surface of the substrate support.

During use in the semiconductor manufacturing process, the substrate support may be surrounded by air. Oxygen and water within the air can cause the substrate support to undergo oxidation, in which a top surface of the substrate support is chemically converted into an oxide film. Water in the air around the top surface of the substrate support may come from humidity in the environment surrounding the substrate support, or from areas around the substrate support where water (as immersion fluid) is present. The oxidation process may be accelerated by the presence of electrostatic charges that build up on an underside of the substrate.

The oxide film formed is typically softer than the material of the substrate support or the material of the substrate support coating. Relative movement during clamping and unclamping can cause the oxide film to be abrasively removed. This tribo-corrosion process leads to degradation in the flatness of the substrate support.

Further, the oxide film is hydrophilic, so in substrate supports used in conjunction with water as an immersion fluid, the water radially outward of the substrate support is attracted into the region between the substrate and the substrate support. This increases adhesive capillary forces, which can cause changes in the pattern of distortion of the substrate (which may be referred to as a distortion fingerprint or wafer load grid (WLG)).

It is an object of the present invention to inhibit the formation of an oxide film on the top surface of the substrate support, to mitigate substrate support flatness drift and changes in the pattern of distortion of the substrate.

According to the present invention, there is provided a substrate holding system comprising a substrate support configured to support a substrate, a gas source, and a plurality of conduits, wherein:
the substrate support comprises a first port in a central region thereof and a plurality of second ports radially outwards of the first port;
the first port and the plurality of second ports are configured to be in fluid communication with the gas source via the plurality of conduits;
the gas source is configured to supply an inert gas to a region between the substrate and the substrate support via a first conduit and the first port, and via a second conduit and the plurality of second ports;
the substrate holding system is configured such that the inert gas can be supplied to the region between the substrate and the substrate support through the first port or the plurality of second ports; and
the substrate holding system is configured to extract gas from the region between the substrate and the substrate support through the plurality of second ports.

According to the present invention, there is also provided a lithographic apparatus including a substrate holding system.

According to the present invention, there is also provided a method of supporting a substrate on a substrate support, the substrate support comprising a first port in a central region of the substrate support and a plurality of second ports radially outwards of the first port, the method comprising:
a substrate loading step in which an inert gas is supplied to a region between the substrate and the substrate support through the plurality of second ports; and
a subsequent substrate clamp step in which the inert gas is supplied to the region between the substrate and the substrate support through the first port.

According to the present invention, there is also provided a method of manufacturing a device including a method of supporting a substrate.

Further embodiments, features and advantages of the present invention, as well as the structure and operation of the various embodiments, features and advantages of the present invention are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts a schematic overview of a lithographic apparatus;

FIG. 2 depicts a cross-sectional view of a radially outer section of a substrate support;

FIGS. 3A-3C depict a cross-sectional view of a substrate support of a substrate holding system, not in accordance with the present invention, in a loading sequence;

FIG. 4 depicts a cross-sectional view of a substrate support of a substrate holding system, not in accordance with the present invention, in a clamped state;

FIG. 5 depicts a cross-sectional view of a substrate support of a substrate holding system, not in accordance with the present invention, in an unloading state;

FIG. 6 depicts a plot of the percentage of surface oxidation (O) against exposure time (t) in hours for a substrate support WT with a DLC coating in environments containing air, ultra-pure water and Nitrogen.

FIG. 7 depicts a plot of: (i) the percentage of surface oxidation (O) against exposure time (t) in seconds for a substrate support WT with a DLC coating in an environment containing air and (ii) the contact angle (CA) against exposure time (t) in seconds for a substrate support WT with a DLC coating in an environment containing air.

FIG. 8 depicts, in a plan view, a substrate support of a substrate holding system, in accordance with the present invention;

FIGS. 9A-9C depict a cross-sectional view of a substrate support of a substrate holding system, in accordance with the present invention, in a loading sequence;

FIG. 10 depicts a cross-sectional view of a substrate support of a substrate holding system, in accordance with the present invention, in a clamped state;

FIG. 11 depicts a cross-sectional view of a substrate support of a substrate holding system, in accordance with the present invention, in an unloading state;

FIG. 12 depicts a schematic diagram of a fluid management system of a substrate holding system, in accordance with the present invention.

FIG. 13 depicts a tooling hole with an orifice for providing an inert gas.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

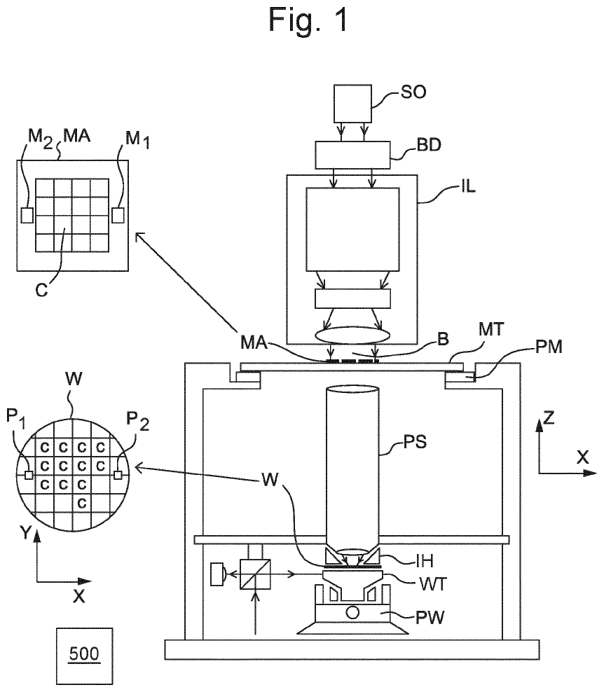

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space between the final element and a surface facing the final element. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure IH present between the projection system PS and the substrate support WT is used to confine the immersion liquid to the immersion space. The immersion space filled by the immersion liquid is smaller in plan than the top surface of the substrate W and the immersion space remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element. The liquid outside the immersion space is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space, removes the immersion liquid from the immersion space and thereby confines the immersion liquid to the immersion space. It includes features which are a part of a fluid supply system. The arrangement disclosed in PCT patent application publication no. WO 99/49504 is an early fluid handling structure comprising pipes which either supply or recover the immersion liquid from the immersion space and which operate depending on the relative motion of the stage beneath the projection system PS. In more recent designs, the fluid handling structure extends along at least a part of a boundary of the immersion space between the final element of the projection system PS and the substrate support WT or substrate W, so as to in part define the immersion space.

The fluid handing structure IH may have a selection of different functions. Each function may be derived from a corresponding feature that enables the fluid handling structure IH to achieve that function. The fluid handling structure IH may be referred to by a number of different terms, each referring to a function, such as barrier member, seal member, fluid supply system, fluid removal system, liquid confinement structure, etc.

As a barrier member, the fluid handling structure IH is a barrier to the flow of the immersion liquid from the immersion space. As a liquid confinement structure, the structure confines the immersion liquid to the immersion space. As a seal member, sealing features of the fluid handling structure IH form a seal to confine the immersion liquid to the immersion space. The sealing features may include an additional gas flow from an opening in the surface of the seal member, such as a gas knife.

The fluid handling structure IH may supply immersion fluid and therefore be a fluid supply system.

The fluid handling structure IH may at least partly confine immersion fluid and thereby be a fluid confinement system.

The fluid handling structure IH may provide a barrier to immersion fluid and thereby be a barrier member, such as a fluid confinement structure.

The fluid handling structure IH may create or use a flow of gas, for example to help in controlling the flow and/or the position of the immersion fluid.

The flow of gas may form a seal to confine the immersion fluid so the fluid handling structure IH may be referred to as a seal member; such a seal member may be a fluid confinement structure.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 1, the lithographic apparatus comprises a controller 500. The controller 500 is configured to control the substrate support WT.

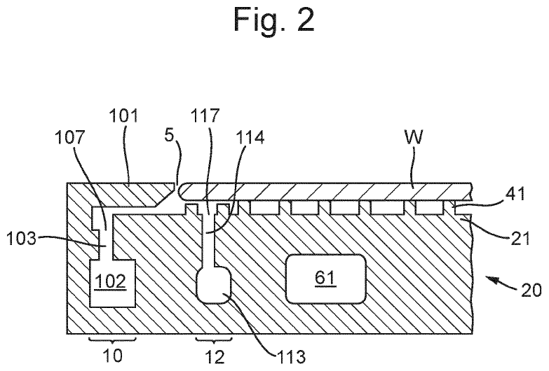

FIG. 2 illustrates part of a lithographic apparatus that is not in accordance with the present invention, but is useful for demonstrating features of the present invention. The arrangement illustrated in FIG. 2 and described below may be applied to the lithographic apparatus described above and illustrated in FIG. 1. FIG. 2 is a cross-section through a substrate support 20 and a substrate W. In an embodiment, the substrate support 20 comprises one or more conditioning channels 61 of a thermal conditioner, which is described in more detail below. A gap 5 exists between an edge of the substrate W and an edge of the substrate support 20. When the edge of the substrate W is being imaged or at other times such as when the substrate W first moves under the projection system PS (as described above), the immersion space filled with liquid by the fluid handling structure IH (for example) will pass at least partly over the gap 5 between the edge of the substrate W and the edge of the substrate support 20. This can result in liquid from the immersion space entering the gap 5.

The substrate W is held by a support body 21 (e.g. a pimple or burl table) comprising one or more burls 41 (i.e., projections from the surface). The support body 21 is an example of an object holder. Another example of an object holder is a mask support. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In the embodiment of FIG. 2 two drains 10, 12 are illustrated though there may only be one drain or there could be more than two drains. In an embodiment, each of the drains 10, 12 is annular so that the whole periphery of the substrate W is surrounded.

A primary function of the first drain 10 (which is radially outward of the edge of the substrate W/support body 21) is to help prevent bubbles of gas from entering the immersion space where the liquid of the fluid handling structure IH is present. Such bubbles may deleteriously affect the imaging of the substrate W. The first drain 10 is present to help avoid gas in the gap 5 escaping into the immersion space in the fluid handling structure IH. If gas does escape into the immersion space, this can lead to a bubble which floats within the immersion space. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. The cover ring 101 may be shaped, in plan, as a ring and surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 2, in an embodiment the lithographic apparatus comprises a first extraction channel 102 for the passage therethrough of a two phase flow. The first extraction channel 102 is formed within a block. The first and second drains 10, 12 are each provided with a respective opening 107, 117 and a respective extraction channel 102, 113. The extraction channel 102, 113 is in fluid communication with the respective opening 107, 117 through a respective passageway 103, 114.

As depicted in FIG. 2, the cover ring 101 has an upper surface. The upper surface extends circumferentially around the substrate W on the support body 21. In use of the lithographic apparatus, the substrate support 20 moves relative to the fluid handling structure IH. During this relative movement, the fluid handling structure IH moves across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment the relative movement is provided by movement of both the substrate support 20 under the fluid handling structure IH and movement of the fluid handling structure IH over the substrate support 20.

### Example

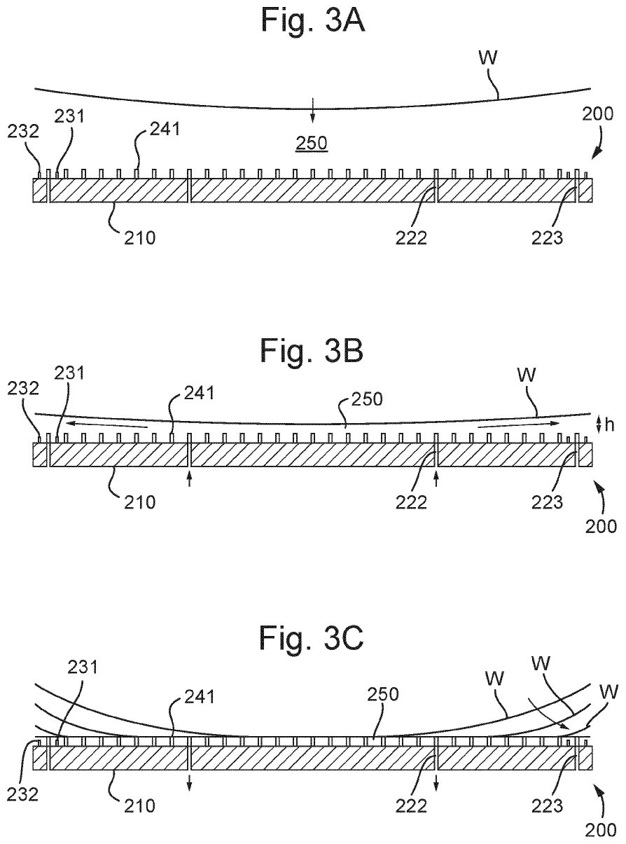

FIGS. 3 to 5 depict a cross-sectional view of a substrate W and a substrate support 210. The substrate support 210 is part of a substrate holding system 200 that is not in accordance with the present invention. The substrate holding system 200 may be integrated in a lithographic apparatus as depicted in FIG. 1. The substrate support 210 may have similar features to those shown in the substrate support 20 in FIG. 2. This example of a substrate holding system 200 and a substrate support 210 is in no way meant to be an acknowledgement of the current state of the art, and serves only to highlight some of the specific advantages of the present invention relative to other possible configurations.

The substrate support 210 may include a support body, as in the substrate support 20 shown in FIG. 2. However, for simplicity, this support body will not be referred to. The substrate support 210 comprises a plurality of burls 241. When the substrate W is supported by the substrate support 210, the substrate W comes into direct contact with the substrate support 210. The distal ends of the burls 241 form a plane at which the underside of the substrate W is supported. The underside of the substrate W comes into contact with the distal ends of the burls 241. The burls 241 are at the upper side of the substrate support 210.

The substrate support 210 depicted in FIGS. 3 to 5 comprises a plurality of multi-functional openings 222 arranged circumferentially around the substrate support 210, and a plurality of extraction openings 223 arranged circumferentially around the substrate support 210, radially outwards of the plurality of multi-functional openings 222.

The substrate holding system 200 is configured to supply clean dry air (CDA) to a region 250 between the substrate support 210 and the substrate W through the plurality of multi-functional openings 222. The substrate holding system 200 is further configured to extract fluid from the region 250 between the support body 221 and the substrate W through the plurality of multi-functional openings 222 and the plurality of extraction openings 223.

The substrate support 210 depicted in FIGS. 3 to 5 comprises an inner seal 231, which is located radially inwards of the plurality of extraction openings 223, and an outer seal 232, which is located radially outwards of the plurality of extraction openings 223.

A sequence for loading a substrate W onto the substrate support 210 is shown in FIG. 3A-3C. As the substrate W is lowered towards the substrate support 210 (FIG. 3A), CDA is supplied to the region 250 between the substrate W and the substrate support 210 (FIG. 3B). For a short period, the substrate W is supported on a cushion of the CDA. After the short period has elapsed, the substrate holding system 200 extracts gas through the plurality of multi-functional openings 222 (FIG. 3C). This reduces the pressure in the region 250 between the substrate W and the substrate support 210 to be less than the ambient pressure, and a clamping force is applied to the underside of the substrate W in a direction towards the substrate support 210, such that the substrate W is clamped to the substrate support 210.

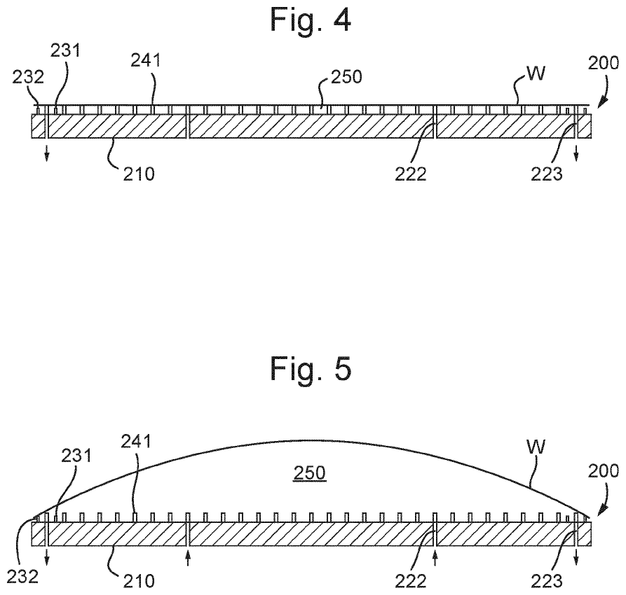

Once the substrate W has been loaded onto the substrate support 210 and the clamping force has been established, the substrate holding system 200 transitions to a clamped state (FIG. 4). In the clamped state, the multi-functional openings 222 may no longer extract gas from the region between the substrate W and the substrate support 210. To maintain the region between the substrate W and the substrate support 210 at a pressure that is less than the ambient pressure, the extraction openings 223 may extract fluid from the region between the substrate W and the substrate support 210. Throughout this clamped state, air from the surrounding environment may enter the region 250 between the substrate W and the substrate support 210 through leaks. For example, air may leak into the region 250 between the substrate W and the substrate support 210 through holes in the body of the substrate support 210. Alternatively, air from the environment could migrate radially inward from the sides of the substrate support 210, past the outer seal 232, plurality of extraction openings 223, and inner seal 231, to reach an inner section of the region 250 between the substrate W and the substrate support 210.

An unloading process for unloading a substrate W from the substrate support 210 is depicted in FIG. 5. In this process, the pressure between the substrate W and the substrate support 210 is increased by introducing CDA through the plurality of multi-functional openings 222. At this time, the extraction openings 223 may continue to extract fluid from the region 250 between the substrate W and the substrate support 210. This may be to remove any immersion fluid from around the inner seal 231 and outer seal 232, and to ensure that the unload sequence is reproducible.

As is clear from the above, in all stages of operation, the top surface of the substrate support 210 is exposed to air. This air contains oxygen, and may contain water. The air may contain water from water vapor in air which has migrated radially inward of the outer seal 232 and the inner seal 231 of the substrate support 210 from the environment surrounding the substrate support 310. Further, in immersion lithography, a region radially outward of the outer seal 232 may be submerged in immersion fluid. This is shown in FIG. 2 as the region below the gap 5. This immersion fluid may be water, for example, ultra-pure water (UPW). In operation, this ultra-pure water, in liquid or vapor form, can also migrate radially inwards towards the center of the substrate support 210, past the outer seal 232, the plurality of extraction openings 223, and the inner seal 231.

When the region between the substrate W and the substrate support 210 contains oxygen and water, oxidation of the upper surface of the substrate support 210 may occur. The plurality of burls 241 are located on the upper surface of the substrate support 210, so the surfaces of the burls 241 may be oxidized. If the substrate support 210 is coated, it may be the coating which is oxidized. Common coatings include materials comprising diamond or diamond-like carbon (DLC). These coatings are susceptible to oxidation in the presence of oxygen and water.

The rate of oxidation is increased by the presence of charges that may build up on the underside of the substrate W. However, oxidation of the top surface of the substrate support 210 cannot be prevented by eliminating this charge build-up, because the oxidation process occurs spontaneously in the presence of oxygen and water (“auto-oxidation”).

The oxide film formed by the oxidation process is typically softer than the material of the substrate support 210 or its coating material. For example, the oxide film formed when DLC is oxidized is softer than DLC itself. This means that, as surfaces move relative to each other during loading and unloading, the oxide film can be mechanically removed. This removal of material causes a degradation in the flatness of the substrate support 210.

Further, the oxide film formed is typically hydrophilic. This means that, when water is used as the immersion fluid, water radially outward of the substrate support 210 may be attracted into the region 250 between the substrate W and the substrate support 210. This can increase the adhesive capillary forces exerted on an underside of the substrate W, which can cause a drift in the wafer load grid (WLG). WLG is a measure of overlay error from residual deformations caused by local sliding during loading.

### Embodiment

Because auto-oxidation requires the presence of oxygen and water, it can be mitigated by removing these components from the area surrounding the substrate support 210. The use of CDA in the above example is aimed at avoiding the presence of water in the region 250 between the substrate W and the substrate support 210, but, as discussed above, water may still be present in the region 250. Therefore, to further mitigate auto-oxidation of the top surface of a substrate support 210, the present invention is directed towards ensuring that there is no, or very little, oxygen or water in a region 250 between the substrate W and the substrate support 210. In the present invention, this is done by providing a substrate holding system 300 that is configured to supply an inert gas to a region 350 between a substrate support 310 and a substrate W throughout the time that the substrate W is clamped to the substrate support 310.

Table 1 shows the difference in the rate of oxidation for a substrate support coated with diamond-like carbon (DLC) in a normal environment (including water and air) and an inert gas environment (N₂ gas). The rate of oxidation was determined by measuring the amount of oxidation products on the surface of the DLC. This is shown as “Increase of oxygen on the surface (%)” in Table 1. The percentage increase of oxygen on the surface of the DLC after 4 days is much lower for the N₂ gas environment (1.20) than the water and air environment (3.50). In the N₂ test, the substrate support environment was flushed with N₂ and then the environment was kept sealed. This means that the results are not fully representative of the potential advantages of the present invention, in which the inert gas is provided to the region 350 between the substrate support 310 and the substrate W throughout the time that the substrate W is clamped to the substrate support 310. However, the results still show that the provision of an inert gas environment to a region between a substrate support and a substrate can have a significant effect on the rate of oxidation.

TABLE 1

| | | Increase of oxygen on the |
|---|---|---|
| Treatment | Duration | surface (%) |
| Water and air | 1 h | 1.25 |
| Water and air | 1 day | 1.75 |
| Water and air | 2 days | 3.25 |
| Water and air | 4 days | 3.50 |
| Nitrogen gas | 4 days | 1.20 |

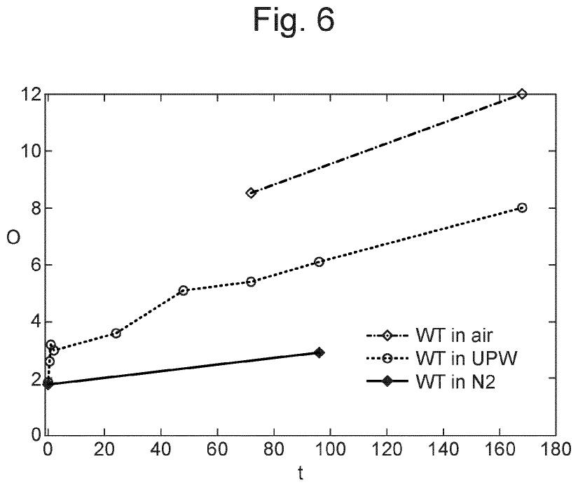

The same relationship is shown in FIG. 6. FIG. 6 depicts a plot of the percentage of surface oxidation (O) on a DLC coating surface against exposure time (t) in hours for a DLC coating on a substrate in environments containing air, ultra-pure water and Nitrogen. The DLC coating is a DLC coating that may be used on a substrate support WT. In this context, the percentage of surface oxidation means the percentage of the DLC coating that is a product of oxidation. The substrates with a DLC coating used to generate the data depicted in FIG. 6 (henceforth, “the samples”) were plasma-treated to obtain a minimum oxidation state of approximately 2%. The samples were then exposed to different environments for time periods ranging from 30 minutes to 4 days. The exposure of samples to auto-oxidative conditions (i.e., in air or ultra-pure water) was performed in a glass petri dish, with a glass cap covering an opening of the petri dish. For the exposure of samples to air, the glass cap did not fully cover the petri dish to allow for the continuous supply of fresh air. The samples exposed to N₂ were exposed in a plastic, sealed glove box-type container containing N₂ gas.

After the predetermined exposure time, the percentage of surface oxidation was determined using X-ray photoelectron spectroscopy (XPS). XPS can measure elemental composition as well as the chemical and electronic state of the atoms within a material.

Contact angle analysis was also performed on the samples. Contact angle (CA) is a measure of the ability of a liquid to wet the surface of a solid. The shape that a droplet takes on a surface depends on the surface tension of the fluid and the nature of the surface. Droplets have a curved shape. The angle between (i) the surface on which the droplet is formed and (ii) the tangent to the curved shape of the droplet at the edge of the droplet (i.e., where the droplet meets the surface on which the droplet is formed) is the contact angle.

As shown in FIG. 6, the percentage of surface oxidation on the surface of the sample increased as exposure time increased. The rate of oxidation was higher for the sample in an environment containing air, and lower for the sample in an environment containing ultra-pure water. The rate of oxidation for the sample in an environment containing N₂ was much lower than the rate of oxidation for the samples in air and ultra-pure water. Consequently, FIG. 6 shows that supplying an inert gas in the region between a substrate support WT and the substrate W can greatly reduce the rate of oxidation on the substrate-facing surface of the substrate support WT. This means that degradation of the flatness of the substrate support WT over time can be avoided. Consequently, the lifetime of the substrate support can be increased.

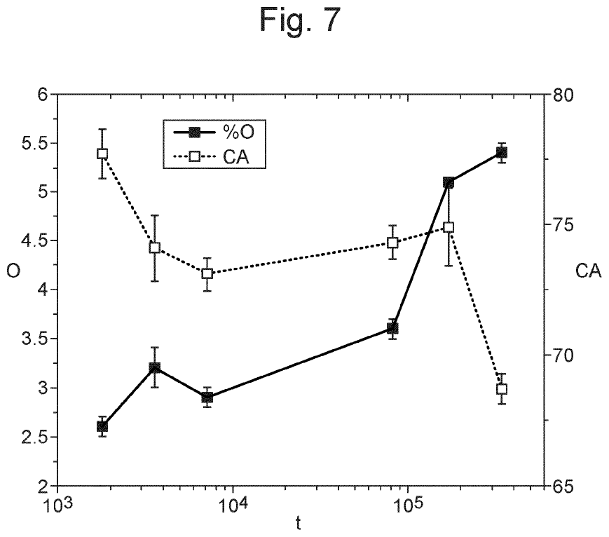

FIG. 7 depicts a plot of: (i) percentage of surface oxidation (O) against exposure time (t) in seconds for a sample (i.e., a substrate with a DLC coating) in an environment containing air and (ii) contact angle (CA) against exposure time (t) in seconds for the sample in an environment containing air. The plot shows that, generally, as the percentage of surface oxidation increases, the contact angle decreases. A high contact angle is indicative of a surface with high hydrophobicity. Consequently, FIG. 7 shows that hydrophobicity decreases as the percentage of surface oxidation increases. Therefore, FIG. 7 demonstrates that as the surface of the substrate support WT is oxidized, it may become more likely to attract water molecules. This means that water radially outward of the substrate support WT is more likely to be attracted into the region 250 between the substrate W and the substrate support WT. This means that adhesive capillary forces exerted on an underside of the substrate W may increase, which can cause a drift in the wafer load grid (WLG). Consequently, decreasing the rate of oxidation by providing an inert gas to the region between the substrate W and the substrate support WT can improve wafer load grid (WLG).

The substrate holding system 300 comprises the substrate support 310, a gas source 382, and a plurality of conduits. As with the substrate holding system 200, the substrate holding system 300 could be integrated in a lithographic apparatus as shown in FIG. 1. However, the invention is not limited to such an implementation of the substrate holding system 300, and the substrate holding system 300 could be used in a variety of other scenarios. For example, this invention could be implemented with lithographic apparatus that do not utilize immersion techniques.

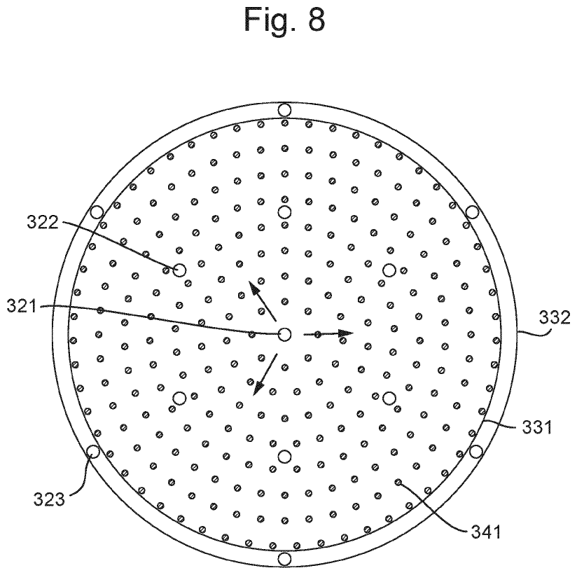

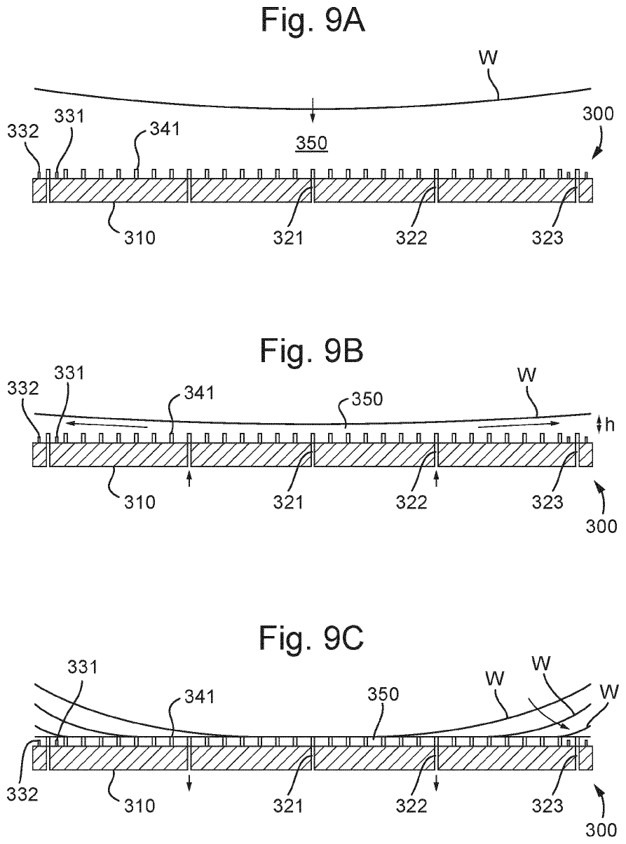

A substrate support 310 which is part of a substrate holding system 300 in accordance with the present invention is depicted in FIGS. 8 to 11. FIG. 8 shows a plan view of the substrate support 310. FIGS. 9 to 11 show a cross-sectional view of the substrate support 310 operating in a number of states. The substrate support 310 is configured to support a substrate W. The substrate support 310 itself may be similar in structure to the substrate support 210 of the previous example, but includes an additional supply opening 321 in a central region of the substrate support 310.

As in the substrate support 210 of the previous example, the substrate support 310 may include a support body. However, for simplicity, this support body will not be referred to. The substrate support 310 may comprise a plurality of burls 341. When the substrate W is supported by the substrate support 310, the substrate W comes into direct contact with the substrate support 310. The distal ends of the burls 341 form a plane at which the underside of the substrate W is supported. The underside of the substrate W comes into contact with the distal ends of the burls 341. The burls 341 are at the upper side of the substrate support 310. The plurality of burls 341 may be arranged in a plurality of circumferential rings. However, the present invention is not limited to this, and the plurality of burls 341 may be arranged in any suitable pattern. The diameter of each burl 341 is not particularly limited. In an embodiment, the burls may have a diameter of approximately 100 to 120 μm. In another embodiment, the burls may have a diameter of approximately 175 μm. The diameter of each of the plurality burls 341 may be the same, or it may vary across the substrate support 310.

A distance between each burl 341 is referred to as a burl pitch. This may be constant throughout the substrate support 310, or it may be varied, as is known to the skilled person. In an embodiment, the burl pitch may be approximately 1.5 mm. In another embodiment, the burl pitch may be approximately 2.5 mm.

The substrate support 310 comprises a supply opening 321 located in a central region of the substrate support 310. For the purposes of this embodiment, the substrate W and substrate support 310 are aligned such that the center of the substrate W and the center of the substrate support 310 are aligned in a direction perpendicular to the upper surface of substrate support 310. This means that the supply opening 321 is located beneath a central region of the substrate W. The substrate support 310 further comprises a plurality of multi-functional openings 322, which may be arranged circumferentially around the substrate support 310, radially outwards of the supply opening 321. The plurality of multi-functional openings 322 may be distributed evenly around the supply opening 321 in the circumferential direction. In a substrate support that is configured to support a substrate W with a diameter of 300 mm, the radial distance between each of the plurality of multi-functional openings 322 and the centre of the substrate support 310 may be more than 40 mm, preferably more than 50 mm, further preferably more than 60 mm. In a substrate support that is configured to support a substrate W with a diameter of 300 mm, the radial distance between each of the plurality of multi-functional openings 322 and the centre of the substrate support 310 may be less than 100 mm, preferably less than 80 mm, and further preferably less than 65 mm. These dimensions can be scaled in accordance with the diameter of the substrate W that the substrate support 310 is configured to support. For example, the radial distance between each of the plurality multi-functional openings 322 and the centre of the substrate support 310 may be more than 13% of the diameter of the substrate W, preferably more than 17% of the diameter of the substrate W, further preferably more than 20% of the diameter of the substrate W. For example, the radial distance between each of the plurality multi-functional openings 322 and the centre of the substrate support 310 may be less than 33% of the diameter of the substrate W, preferably less than 27% of the diameter of the substrate W, and further preferably less than 22% of the diameter of the substrate W.

In an embodiment, the radial distance from the centre of the substrate support 310 to each multi-functional opening 322 may be the same. In another embodiment, the radial distance from the centre of the substrate support 310 to some multi-functional openings 322 may be greater for some multi-functional openings 322 than other multi-functional openings 322. This may be such that the plurality of multi-functional openings 322 are arranged in a plurality of circumferential rings, with the distance from the centre of the substrate support 310 to the multi-functional openings being different for each circumferential ring. The supply opening 321 is an example of a first port. The plurality of multi-functional openings 322 are examples of a plurality of second ports.

The supply opening 321 and plurality of multi-functional openings 322 are configured to be in fluid communication with the gas source 382, via a plurality of conduits 371, 372, 373. The gas source 382 may be configured to supply an inert gas to the supply opening 321 via conduits 371, 372, and to supply the inert gas to the plurality of multi-functional openings 322 via a conduits 371, 373. The substrate holding system 300 may further be configured to extract gas from the region 350 between the substrate W and the substrate support 310 through the plurality of multi-functional openings 322.

The substrate support 310 may further comprise a plurality of extraction openings 323 arranged circumferentially around the substrate support 310, radially outwards of the plurality of multi-functional openings 322. The substrate holding system 300 may be configured to extract fluid from the region 350 between the substrate W and the substrate support 310 through the plurality of extraction openings 323. The plurality of extraction openings 323 may be provided in an edge region of the substrate support 310. The plurality of extraction openings 323 are examples of a plurality of third ports. Instead of a plurality of extraction openings 323, the invention could include a single extraction opening 323 in the form of an annular channel extending circumferentially around the substrate support 310 in the edge region.

The substrate support 310 may further comprise a plurality of seals 331, 332. The seals 331, 332 are circumferential rings protruding from the substrate support 310. In an embodiment, the substrate support 310 comprises an inner seal 331, which is located radially inwards of the plurality of extraction openings 323 but still within the edge region of the substrate support 310, and an outer seal 332, which is located radially outwards of the plurality of extraction openings 323.

The edge region may be a region that is radially outwards of a radially outermost circumferential ring of burls 341. It is the combination of the outer seal 332, plurality of extraction openings 323, and the inner seal 331 that block air and/or immersion fluid from the environment around the substrate support 310 migrating radially inward in the region 350 between the substrate W and the substrate support 310. In an embodiment in which the substrate support 310 is configured to support a substrate W with a diameter of 300 mm, the edge region of the substrate support 310 may be a region in which, when the substrate W is supported on the substrate support 310, the distance to the circumferential edge of the substrate W is less than 50 mm, preferably less than 25 mm, and further preferably less than 10 mm. The distance between the plurality of extraction openings 323 and the edge of the substrate W may be less than 25 mm, preferably less than 10 mm, further preferably less than 5 mm, and greater than 1.5 mm.

These dimensions can be scaled for substrate supports 310 that are configured to support substrates W with alternate diameters. For example, when a substrate W is supported on the substrate support 310, the distance between each of the plurality of extraction openings 323 and the circumferential edge of the substrate W may be less than 10% of the diameter of the substrate W, preferably less than 4% of the diameter of the substrate W, further preferably less than 2% of the diameter of the substrate W, and greater than 0.5% of the diameter of the substrate W.

In an embodiment, when the substrate W is supported by the substrate support 310, top surfaces of the inner seal 331 and the outer seal 332 (that is, surfaces of the inner and outer seals 331, 332 that are substantially parallel with and closest to the substrate W) do not contact the underside of the substrate W. However, the distances between the top surfaces of the inner seal 331 and the outer seal 332 and the underside of the substrate W are such that at least a partial seal is formed between the top surfaces of the seals 331, 332 and the underside of the substrate W. That is, on their own, the seals 331, 332 inhibit, but do not fully prevent, the flow of fluid between the region 350 between the substrate W and the substrate support 310 a region radially outward of the substrate support 310. The distance between the top surfaces of the seals 331, 332 and the underside of the substrate W may be smaller than 10 μm and preferably smaller than 5 μm, and preferably larger than 1 μm and preferably larger than 3 μm. Consequently, the flow of inert gas from the center of the substrate support 310 to the extraction openings 323 serves to reinforce the inner seal 331, preventing air from the region radially outward of the substrate support 310 entering the region 350 between the substrate W and the substrate support 310.

The width of the inner seal 331 and the outer seal 332 (that is, the distance in the radial direction between the seal's inner circumferential edge and the seal's outer circumferential edge) may be preferably greater than 0.1 mm, and further preferably greater than 0.2 mm. The width of the inner seal 331 and the outer seal 332 may be preferably less than 1 mm and further preferably less than 0.6 mm.

The substrate holding system 300 may be configured to perform a loading sequence, to operate in a clamped state, and to perform an unloading sequence.

FIGS. 9A to 9C depict the substrate support 310 of the substrate holding system 300 in three stages of the loading sequence. FIG. 9A shows the substrate W being lowered towards the substrate support 310. The method of lowering the substrate W towards the substrate support 310 is not particularly limited. As an example, the substrate W may first be received by a plurality of extendable pins in their extended position (not shown). The pins may then retracted such that the substrate W is lowered towards the substrate support 310. When the underside of the substrate W comes into contact with the plurality of burls 341, the pins continue to retract such that the substrate W is no longer in contact with the pins, and the substrate W is fully supported by the plurality of burls 341. However, the present invention is not limited to this method of lowering the substrate W towards the substrate support 310, and it will be appreciated that the person skilled in the art could implement any known technique for lowering the substrate W towards the substrate support 310.

As the substrate W approaches the substrate support 310, inert gas is provided to a region 350 above the substrate support 310 from the gas source 382, via the plurality of conduits 371, 372, 373 and the multi-functional openings 322 (see FIG. 9B). As the substrate W approaches the substrate support 310, the pressure in the region 350 between the substrate W and the substrate support 310 increases to be larger than the ambient pressure, and the substrate W lands on a cushion of the inert gas. That is, the substrate W is supported by the inert gas provided to the region 350 between the substrate W and the substrate support 310. The substrate W may be supported in such a way that there is a small gap (h) between the substrate support 310 and the substrate W. This gap (h) may preferably be greater than 50 μm, preferably greater than 80 μm, further preferably greater than 100 μm. This gap (h) may preferably be less than 500 μm, preferably less than 250 μm, and further preferably less than 200 μm. Whilst the substrate W is supported on the cushion of the inert gas, the inert gas supplied from the multi-functional openings 322 flows radially outwards in the region 350 between the substrate W and the substrate support 310 to the edge of the substrate W.

The substrate W may be supported on the cushion of inert gas for a predetermined time. The predetermined amount of time may be dependent on the flow rate of the inert gas through the plurality of multi-functional openings 322. The predetermined time may be that required to ensure that the vast majority of any air from the environment that comes between the substrate W and the substrate support 310 during the lowering of the substrate W towards the substrate support 310 has been replaced by the inert gas. In an embodiment, this amount of time may be greater than 10 ms, preferably greater than 20 ms. In an embodiment, this amount of time may be less than 500 ms, and preferably less than 200 ms. However, the invention is not limited to the substrate W being supported on the cushion of inert gas for a predetermined amount of time, and, for example, the substrate W may be supported on the cushion of inert gas until a sensor 378 reading reaches a predetermined threshold.

After the substrate W has landed on the cushion of inert gas and the predetermined time has elapsed (or after the sensor 378 reading has reached the predetermined threshold), the inert gas is no longer supplied to the region 350 between the substrate W and the substrate support 310 via the plurality of multi-functional openings 322. Instead, the substrate support 310 switches to extracting gas from the region 350 between the substrate W and the substrate support 310 via the plurality of multi-functional openings 322 (FIG. 9C). In doing this the pressure in the region 350 between the substrate W and the substrate support 310 is reduced to become less than the ambient pressure, and a force is applied to the underside of the substrate W in a direction towards the substrate support 310, such that the substrate W is clamped to the substrate support 310.

By performing this loading sequence, it is ensured that, at the time that the substrate W is first clamped to the substrate support 310, the vast majority of the gas in the region 350 between the substrate W and the substrate support 310 is inert gas, rather than air, which contains oxygen, and potentially water.

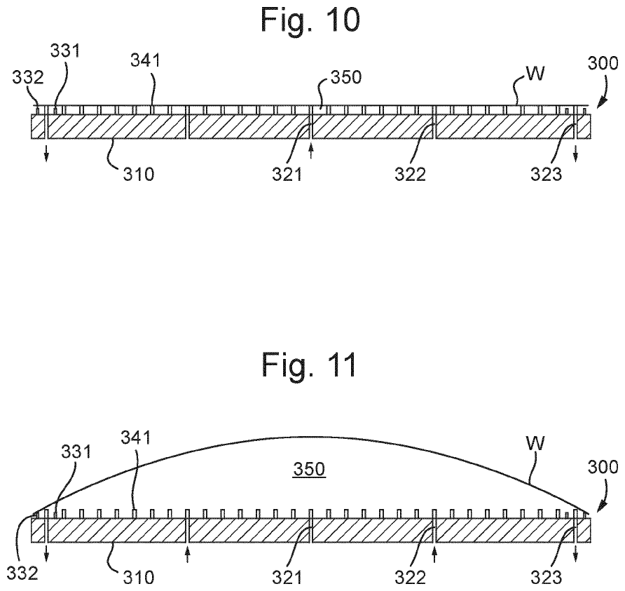

The clamped state that the substrate holding system 300 is configured to operate in is shown in FIG. 10. In this state, the inert gas is supplied to the region 350 between the substrate W and the substrate support 310 from the gas source 382, and through the supply opening 321. In an embodiment, in the clamp state, the inert gas is supplied to the region 350 between the substrate W and the substrate support 310 through only the supply opening 321. In another embodiment, in the clamp state, the inert gas is supplied to the region 350 between the substrate W and the substrate support 310 through the supply opening 321 and the plurality of multi-functional openings 322.

The substrate holding system 300 performs the clamped state for the majority of the time that the substrate W is clamped to the substrate support 310. The substrate holding system 300 may perform the clamped state for the entirety of the time that the substrate W is supported by the substrate support 310, except for during the loading and unloading sequences. If the substrate holding system 300 is implemented within a lithographic apparatus, the substrate holding system 300 may operate in the clamped state for the entirety of a time that the lithographic apparatus is performing an exposure process on the substrate W. In general, the substrate holding system 300 may operate in the clamped state for 90% of the time that the substrate holding system 300 is in operation, and preferably 95% of the time that the substrate holding system 300 is in operation.

In the clamped state, the flow rate of inert gas is sufficient to establish or maintain an inert gas environment in the region 350 between the substrate W and the substrate support 310. An inert gas environment is an environment in which the vast majority of the gas is inert gas. In this aspect, the vast majority may mean greater than 90%, preferably greater than 95%, and further preferably greater than 99%. In the clamped state, the flow rate of the inert gas through the supply opening 321 may be greater than 1 NLpm (normal litre per minute, i.e. the flow rate in litres per minute if the gas were to be at standard temperature and pressure), preferably greater than 1.5 NLpm, further preferably greater than 1.8 NLpm. In the clamped state, the flow rate of the inert gas through the supply opening 321 may be less than 10 NLpm, preferably less than 5 NLpm, and further preferably less than 2.5 NLpm. For example, the flow rate of the inert gas may be 2 NLpm. With this flow rate, an inert gas environment may be established in the region 350 between the substrate W and the substrate support 310 in approximately 350 ms. This means that the time in which the substrate support 310 is exposed to oxidative conditions can be reduced by approximately 98%, depending on the timing of the loading and unloading sequences.

By providing the inert gas to the region 350 between the substrate W and the substrate support 310 for the majority of the time that the substrate W is clamped to the substrate support 310, it can be ensured that throughout the time that the substrate W is clamped to the substrate support 310, the majority of gas present in the region 350 between the substrate W and the substrate support 310 is the inert gas, and not air from the surrounding environment, which contains oxygen and may contain water. For example, even if leaks are present within the substrate support 310, such that air from the environment can enter the region 350 between the substrate W and the substrate support 310, the constant flow of inert gas from the supply opening 321 to the extraction openings 323, and the constant extraction of fluid from the extraction openings 323, means that the air is quickly removed and replaced with the inert gas, before it can cause any significant oxidation of the upper surface of the substrate support 310.

The supply opening 321 is located in a central region of the substrate support 310. In an embodiment, the central region may be a region in which the radial distance to the center of the substrate support 310 is less than 25 mm, preferably less than 15 mm, and further preferably less than 10 mm. In an embodiment, the supply opening 321 may be located in the center of the substrate support 310. The substrate holding system 300 and the substrate support 310 may be configured such that, after the inert gas has been supplied via the supply opening 321, the inert gas flows radially outwards towards the edge of the substrate W. Therefore, by providing the inert gas to the region 350 between the substrate W and the substrate support 310 through the supply opening 321 that is located in a central region of the substrate support 310, it can be ensured that the inert gas is distributed throughout the region 350 between the substrate W and the substrate support 310.

In the clamped state, the extraction openings 323 may extract fluid from the region 350 between the substrate W and the substrate support 310 so that the clamping pressure (that is, the difference between the pressure in the region 350 between the substrate W and the substrate support 310 and the ambient pressure) can be maintained throughout the time that the clamped state is in operation. In an embodiment, the magnitude of the clamping pressure is greater than 100 mbar, preferably greater than 300 mbar, further preferably greater than 350 mbar. In an embodiment, the magnitude of the clamping pressure is less than 800 mbar, preferably less than 500 mbar, and preferably less than 450 mbar. The extraction of fluid from the region 350 between the substrate W and the substrate support 310 via the extraction openings 323 occurs because the extraction openings 323 are in fluid communication with a region of pressure that is lower than the pressure in the region 350 between the substrate W and the substrate support 310. The substrate holding system 300 may be configured such that the plurality of extraction openings 323 are in fluid communication with a region of pressure that is greater than 400 mbar less than ambient pressure, preferably greater than 550 mbar less than ambient pressure, further preferably greater than 650 mbar less than ambient pressure, less than 800 mbar less than ambient pressure, and preferably less than 750 mbar less than ambient pressure. The region of reduced pressure that the plurality of extraction openings 323 are in fluid communication with is formed by the vacuum pressure source 381.

The substrate holding system 300 may be configured such that the plurality of extraction openings 323 can extract fluid from the region 350 between the substrate W and the substrate support 310 at a rate that is greater than 10 NLpm, preferably greater than 25 NLpm, and further preferably greater than 29 NLpm.

Because the pressure at the plurality of extraction openings 323, which are located in the edge region of the substrate support 310, is lower than the pressure throughout the rest of the region 350 between the substrate W and the substrate support 310, inert gas that is supplied to the central region of the substrate support 310 flows radially from the central region of the region 350 between the substrate W and the substrate support 310 towards the plurality of extraction openings 323. This ensures that the inert gas is distributed throughout the region 350 between the substrate W and the substrate support 310. Further, the flow of inert gas towards the edge of the region 350 between the substrate W and the substrate support 310 reinforces the inner seal 331 and the outer seal 332 in preventing air and water migrating radially inwards from the area surrounding the substrate support 310.

An unloading step of a substrate W unloading sequence is depicted in FIG. 11. This step of the unloading sequence may occur after the substrate holding system 300 has been operating in the clamped state. To transition from the clamped state to the step of the unloading sequence depicted in FIG. 11, the inert gas is supplied to the region 350 between the substrate W and the substrate support 310 through the plurality of multi-functional openings 322. This means that the pressure in the region 350 between the substrate W and the substrate support 310 increases. The pressure in the region 350 between the substrate W and the substrate support 310 may increase to be the same as the ambient pressure, in which case the clamping force exerted on the substrate W is completely released. The pressure in the region 350 between the substrate W and the substrate support 310 may increase to be greater than the ambient pressure. In this case, a force is exerted on the underside of the substrate W in an upward direction (i.e., a direction that is away from the substrate support 310).

In this step of the unloading sequence, the plurality of extraction openings 323 may extract fluid from the region 350 between the substrate W and the substrate support 310. This may happen at the same time that the inert gas is supplied to the region 350 between the substrate W and the substrate support 310. Consequently, the pressure in the region may vary radially in the region 350 between the substrate W and the substrate support 310. Specifically, the pressure may be higher in a radially inward region, and lower in a radially outward region. In the radially inward region, the pressure may be greater than the ambient pressure, and in the radially outward region, the pressure may be lower than the ambient pressure. In this case, a force is applied to the underside of the substrate W that is in an upward direction (i.e. in a direction away from the substrate support 310) in the inner region of the substrate W, and a downward direction (i.e. in a direction towards to the substrate support 310) in the outer region of the substrate W. This may cause the substrate to deform into an umbrella shape, in which the substrate is curved such that the distance between the substrate W and the substrate support 310 is greater at the center of the substrate W than at the edges. This may mean that the substrate W is in contact with the plurality of burls 341 at the edge of the substrate support 310, but not the plurality of burls 341 in the middle of the substrate support 310.

The inert gas introduced through the plurality of multi-functional openings 322 will flow radially outward to be extracted by the plurality of extraction openings 323. This circulating flow ensures that any immersion fluid around the inner seal 331 and outer seal 332 is removed prior to the substrate W being unloaded from the substrate support 310. This ensures that the load sequence is reproducible. Because the gas supplied to the plurality of multi-functional openings 322 is an inert gas, rather than, for example, air, it is ensured that the region 350 between the substrate W and the substrate support 310 does not contain any significant amount of oxygen during this stage of the unloading sequence.

The unloading sequence may continue with the plurality of extendable pins (not shown) being extended from their retracted position, such that distal portions of the extendable pins come into contact with the underside of the substrate W. As the plurality of extendable pins continue to extend, the substrate W is lifted upwards (i.e. away from the substrate support 310), such that the substrate W is no longer in contact with the plurality of burls 341.

When the inert gas is supplied in the clamped state and in the unloading sequence, it may be extracted by the plurality of extraction openings 323. These extraction openings 323 are required irrespective of the supply of inert gas for the purpose of maintaining the clamping pressure in the region 350 between the substrate W and the substrate support 310. Therefore, according to the present invention, there is no requirement for an additional extraction opening to extract the inert gas.

Because the substrate support 310 is provided with a supply opening 321 and a plurality of multi-functional openings 322, and the substrate holding system 300 may be configured such that inert gas can be provided in one but not the other, the inert gas can be supplied to the supply opening 321 during the clamped state and the multi-functional openings 322 during the loading and unloading sequences. It is important that the inert gas is provided to a central region of the substrate support 310 during the clamped state, because, since the inert gas flows radially outwards once it has been supplied to the region 350 between the substrate W and the substrate support 310, this ensures that all of the region 350 between the substrate W and the substrate support 310 is surrounded by the inert gas. Conversely, it is important that the inert gas is provided to a region that is radially outwards of the central region during the loading and unloading sequences. This is because if the inert gas were to be supplied to the central region during the loading and unloading sequences, the resulting pressure distribution on the underside of the substrate W could cause a flatness bump in a central region of the substrate W.

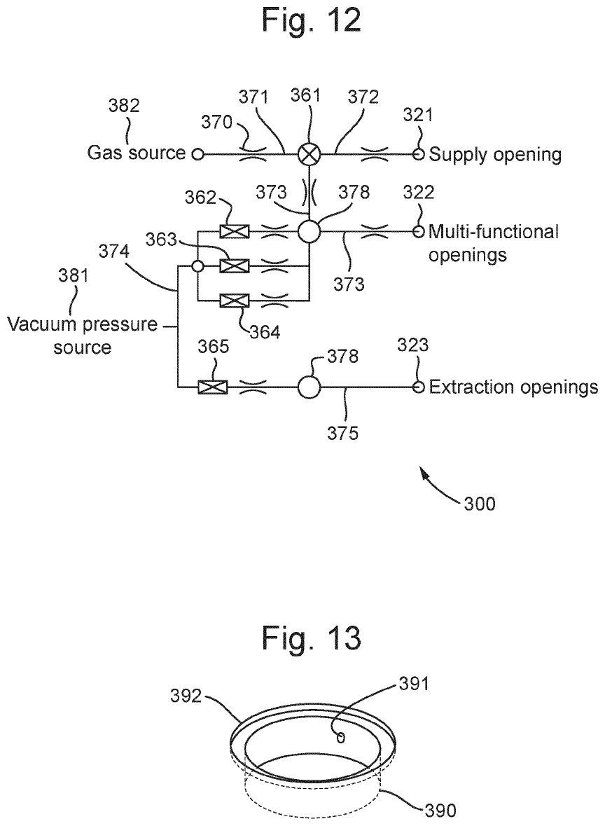

One example of a configuration of a fluid management system of the substrate holding system 300 is shown in FIG. 12. In the configuration depicted, the gas source 382 is connected to the multi-functional openings 322 and the supply opening 321 via an inert gas supply valve 361. The inert gas supply valve 361 may be a 3-way valve, with a first opening corresponding to an inert gas supply conduit 371, a second opening corresponding to a supply opening conduit 372, and a third opening corresponding to a multi-functional openings conduit 373. The inert gas supply valve 361 may be configured to supply the inert gas to neither of the supply opening conduit 372 or the multi-functional openings conduit 373, to supply the inert gas to the supply opening conduit 372 only, and to supply the inert gas to the multi-functional openings conduit 373 only. The inert gas supply valve 361 may be further configured to supply the inert gas to the supply opening conduit 372 and the multi-functional openings conduit simultaneously 373. In this way, only the inert gas supply valve 361 is required to provide the inert gas supply functionality of the present invention. This means that the system is simple, easy to assemble and easy to maintain.

Alternatively, the inert gas supply valve 361 may be a 4-way valve. A 4-way inert gas supply valve 361 may include the same three ports as the 3-way inert gas supply valve 361, with an additional port configured to exhaust the inert gas to an external environment, or to other parts of the substrate holding system 300. The type of valve used for the inert gas supply valve 361 is not particularly limited, and any suitable valve known to a person skilled in the art could be used.

The invention is not limited to this configuration of supplying the inert gas to the supply opening 321 and the plurality of multi-functional openings 322. For example, the flow of inert gas from the gas source 382 to the supply opening 321 and the plurality of multi-functional openings 322 may not be controlled by a single inert gas supply valve 361. In this case (not shown), the flow of inert gas to the supply openings 321 may be controlled by a first 2-way valve, with an inlet opening connected to a first inert gas supply conduit and an outlet opening connected to the supply opening conduit. The flow of inert gas to the plurality of multi-functional openings 322 may be controlled by a second 2-way valve, with an inlet opening connected to a second inert gas supply conduit and an outlet opening connected to the multi-functional openings conduit.

As is also depicted in FIG. 12, the plurality of multi-functional openings 322 and the plurality of extraction openings 323 are in fluid communication with a vacuum pressure source 381. This vacuum pressure source 381 provides a region of pressure that is lower than ambient pressure. Consequently, the vacuum source 381 causes gas to be extracted through the multi-functional openings 322 and the plurality of extraction openings 323. In the configuration shown in FIG. 12, the flow-path between the vacuum source 381 and the multi-functional openings 322 is distinct from the flow-path between the vacuum pressure source 381 and the plurality of extraction openings 323. Each flow-path may comprise a valve to control the extraction of fluid from the corresponding opening. The valve may be a simple 2-way valve, with an inlet opening connected to a vacuum source conduit 374, and an outlet opening connected to a conduit 373, 375 corresponding to the multi-functional openings 322 or the extraction openings 323. For example, the flow-path between the vacuum pressure source 381 and the extraction openings 323 may include a 2-way valve 365.

Flow restrictions 370 (also known as control valves) may be included within the fluid management system. The flow restrictions 370 may be configured to control the flow of fluids through the conduits 371, 372, 373, 374. The type of flow restriction 370 used is not particularly limited. For example, the flow restriction 370 may be a needle valve, a solenoid valve, or any other appropriate type of control valve known to a person skilled in the art. It is not necessary for each of the flow restrictions 370 to be the same. In fact, each flow restriction 370 may have different properties so that the flow of fluid through the system can be tailored in different sections of conduit. This may be so that the rate of fluid supply/extraction can be made different at different openings or at different times. The flow restrictions 370 shown in FIG. 12 are examples, and further restrictions could be included, or some of the restrictions omitted, to provide the required flow characteristics.

The fluid management system may include a plurality of additional valves, such as check valves (non-return valves), relief valves, isolation valves etc.

In the fluid management system, there may be a plurality of paths between the vacuum pressure source 381 and the plurality of multi-functional openings 322. Each path may comprise a valve 362, 363, 364 and a flow restriction 370. Each flow restriction 370 may be configured in a different way. For example, each flow restriction 370 may be configured to allow fluid to flow through at a different volumetric flow rate. Consequently, the extraction flow rate from the plurality of multi-functional openings 322 can be controlled by changing the valve out of the valves 362, 363, 364 which is open. However, this is only one example configuration of the present invention, and the flow extraction path is not limited to this configuration. For example, the branch between the vacuum pressure source 381 and the plurality of multi-functional openings 322 may not split into a plurality of paths. The flow-rate of fluid may instead be controlled by a variable flow restriction valve.

The substrate holding system 300 may comprise a plurality of sensors 378. The plurality of sensors 378 may be distributed throughout the fluid management system. These sensors 378 may measure a plurality of fluid characteristics, such as: mass flow rate; volumetric flow rate; pressure; temperature; flow velocity; fluid composition. These sensed characteristics may be relayed to a monitoring system. This monitoring system may be configured to change aspects of the functioning of the flow system in response to the measured values. The monitoring system may be included in the substrate holding system 300, or it may be external to the substrate holding system 300.

The term “conduit” has been used throughout this description to refer to the passageways fluidly connecting different components in the substrate holding system 300. The term “conduit” is not limited to fixed, rigid pipes, and is intended to encompass all appropriate fluid passageways and connections known to a person skilled in the art.

In the above embodiment, a single supply opening 321 has been referred to. However, the present invention is not limited to this, and the substrate support 310 comprise have a plurality of supply openings 321, each configured in the same way as the single supply opening 321 described above. A plurality of supply openings 321 may all be located in the central region. Alternatively, some of the supply openings 321 may be located in the central region, but others may be located radially outwards of the central region. The diameter of each supply opening 321 may be such that the supply opening 321 itself does not induce effects such as a pressure drop or turbulence in the flow of inert gas from the gas source 382 to the region 350 between the substrate W and the substrate support 310. Consequently, the diameter of each supply opening 321 may depend on the flow rate of inert gas being supplied to the region 350 between the substrate W and the substrate support 310, and the number of supply openings 321.

In an embodiment in which there is only a single supply opening 321, the diameter of the supply opening 321 may be greater than 0.6 mm, preferably greater than 0.8 mm, further preferably greater than 1 mm and further preferably greater than 1.1 mm. In an embodiment in which there are a plurality of supply openings 321, the diameter of each of the supply openings 321 may be greater than 0.4 mm and preferably greater than 0.6 mm.

So that the supply openings 321 do not interfere with the plurality of burls 341, the diameter of the supply openings 321 may be less than the sum of the burl pitch and the burl radius. For example, if the burl pitch is 1.5 mm, the diameter of the supply opening(s) may be less than 1.2 mm. If the burl pitch is 2.5 mm, the diameter of the supply opening(s) may be less than 2.1 mm.

In an embodiment of the present invention, the upper surface of the substrate support 310 may include a plurality of further openings (not shown in FIGS. 8 to 11). These openings may be present to provide an entry point for tooling, or to house the plurality of extendable pins that are used to lower/raise the substrate W towards/away from the substrate support 310 during loading and unloading sequences. An example of a tooling opening 390 is shown in FIG. 13. It may be the case that the region inside the tooling opening 390 is required to remain at ambient pressure. In previous configurations of substrate supports 310, the gas within holes such as the tooling opening 390 would have been air at ambient pressure. Whilst the tooling opening 390 may have been provided with a seal 392 to inhibit the flow of air from the area inside the tooling opening 390 to the region 350 between the substrate W and the substrate support 310, leakage at this seal 392 would have meant that a region surrounding the tooling opening 390 would have been exposed to air. The oxygen and, potentially, water in this leaked air could have caused oxidation to the upper surface of the substrate support W in the region surrounding the tooling opening 390. This could have caused a localized flatness drift.

In an embodiment of the present invention, each of these tooling openings 390 may comprise a small orifice 391. The substrate holding system 300 may be configured to supply inert gas to the area inside the tooling opening 390 through the small orifice 391, so that the pressure inside the tooling opening 390 is ambient pressure, but the tooling opening 390 contains inert gas, rather than air. This means that any gas which flows from the area inside the tooling opening 390 beyond the seal 392 to the main region 350 between the substrate W and the substrate support 310 is inert, and does not contain oxygen. This means that oxidation in the regions around openings used for purposes such as tooling and the provision of extendable pins is avoided, and there is no localized flatness drift in these areas.

In the present invention, it is only required that the gas source 382 and the substrate support 310 are included in the substrate holding system 300. However, the invention is not limited to these components being located in an exact location within the substrate holding system 300. If the substrate holding system 300 comprises further components, the location of these other components within the substrate holding system 300 is not limited. For example, if the substrate holding system 300 comprises the inert gas supply valve 361, the location of the inert gas supply valve 361 is not limited. In an embodiment, the inert gas supply valve 361 may be located within the substrate support 310 itself. However, the inert gas supply valve 361 may instead be located within the gas source 382, or at a location between the substrate support 310 and the gas source 382.

The structure of the gas source 382 is not particularly limited, and any configuration known to be suitable by a person skilled in the art could be utilized in an embodiment of the present invention. The gas source 382 may itself have a storage component configured to store the inert gas, or the gas source may be connected to an external system configured to supply a constant flow of the inert gas to the gas source 382. The structure of the vacuum pressure source 381 is also not particularly limited, and any configuration known to be suitable to a person skilled in the art could be utilized in an embodiment of the present invention.

The inert gas may consist essentially of Nitrogen (N₂). That is, the vast majority of the inert gas may be Nitrogen. Specifically, the proportion of Nitrogen in the inert gas may be greater than 90%, preferably greater than 95%, preferably greater than 99%, and further preferably greater than 99.5%. The proportion of the other components in the inert gas should be sufficiently low such that they do not contribute to any significant oxidation of the substrate support 310. Nitrogen is particularly favorable because it is relatively cheap and easy to obtain, and comes from a plentiful resource (the air). Nitrogen in the quantities used in the present invention does not present a safety concern. However, the inert gas of the present invention is not limited to being Nitrogen, and could alternatively be any gas that does not contain oxygen or water, and is known not to react with the material of the substrate support body and/or coating. For example, Helium (H₂) and Argon (Ar) could also be used.

In addition to preventing oxidation of the surface of the substrate support 310, when providing an inert gas to the region 350 between the substrate W and the substrate support 310, it can be ensured that the gas is clean, and does not contain debris. Debris can have an adverse impact on the operation of the substrate holding system 300. For example, debris can cause a degradation in the flatness of the substrate W, or can cause damage to sensitive components.

The substrate support 310 can be formed from any material known in the art. For example, the substrate support 310 may be formed from SiSiC. The substrate support 310 may be coated. The type of coating is not particularly limited, and may be any coating known to a person skilled in the art to be suitable for the application. For example, the substrate support 310 may be coated with diamond, or diamond-like carbon (DLC).

In the claims, the term “port” is used to mean “an opening for the passage of fluid”. The term “port” does not imply any geometrical constraints on the opening for the passage of fluid. For example, even though throughout the figures the ports are shown to be holes with a cylindrical cross-section, the invention is not limited to this configuration, and the ports may be other shapes.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc.

Specifically, the lithographic apparatus may comprise the projection system PS configured to project the radiation beam B towards the region of the surface of a substrate W. The lithographic apparatus may further comprise the substrate holding system 300 as described in any of the above embodiments and variations.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A substrate holding system comprising:
a substrate support configured to support a substrate, the substrate support comprising a first port in a central region thereof and a plurality of second ports radially outwards of the first port;
a gas source configured to supply an inert gas to a region between the substrate and the substrate support via the first port, and via the plurality of second ports; and
a plurality of conduits configured to provide fluid communication between the gas source and the first port and plurality of second ports, wherein:
the substrate holding system is configured such that the inert gas can be supplied to the region between the substrate and the substrate support through the first port or the plurality of second ports; and
the substrate holding system is configured to extract gas from the region between the substrate and the substrate support through the plurality of second ports.

2. The substrate holding system according to claim 1, wherein the first port and the plurality of second ports are in fluid communication with the gas supply via at least one valve in the substrate holding system, wherein the at least one valve is configured such that the inert gas can be supplied to the region between the substrate and the substrate support through the first port or the plurality of second ports.

3. The substrate holding system according to claim 2, wherein the valve is further configured to exhaust the inert gas to an external environment or to other parts of the substrate holding system.

4. The substrate holding system according to claim 1, wherein the substrate support further comprises a plurality of third ports radially outwards of the plurality of second ports, wherein the plurality of third ports are configured to extract fluid from the region between the substrate and the substrate support.

5. The substrate holding system according to claim 4, wherein the plurality of third ports are configured to be in fluid communication with a region of pressure that is greater than 400 mbar less than ambient pressure and less than 800 mbar less than ambient pressure.

6. The substrate holding system according to claim 1, wherein the central region of the substrate support is a region in which the radial distance to the centre of the substrate support is less than 25 mm.

7. The substrate holding system according to claim 1, wherein the radial distance between each of the plurality of second ports and the centre of the substrate support is more than 40 mm and less than 100 mm, and/or wherein the radial distance between each of the plurality of second ports and the centre of the substrate support is more than 13% of the diameter of the substrate and less than 33% of the diameter of the substrate.

8. The substrate holding system according to claim 4, wherein, when the substrate is supported on the substrate support, the distance between each of the plurality of third ports and a peripheral edge of the substrate is less than 25 mm and greater than 1.5 mm, or wherein, when the substrate is supported on the substrate support, the distance between each of the plurality of third ports and a circumferential edge of the substrate is less than 10% of the diameter of the substrate and greater than 0.5% of the diameter of the substrate.

9. The substrate holding system according to claim 1, wherein there is only one first port in the central region of the substrate support, and the diameter of the first port is greater than 0.6 mm, or wherein there are a plurality of first ports in the central region of the substrate support.

10. The substrate holding system according to claim 9, wherein there are a plurality of first ports in the central region of the substrate support and the diameter of each of the plurality of first ports is greater than 0.4 mm.

11. The substrate holding system according to claim 1, wherein the substrate support further comprises a plurality of burls protruding from an upper surface of the substrate support.

12. The substrate holding system according to claim 11, wherein the diameter of the first port is less than the sum of the distance between each of the plurality of burls and the radius of each burl.

13. A lithographic apparatus including the substrate holding system according to claim 1.

14. A method of supporting a substrate on a substrate support, the substrate support comprising a first port in a central region of the substrate support and a plurality of second ports radially outwards of the first port, the method comprising:
supplying, in a substrate loading, an inert gas to a region between the substrate and the substrate support through the plurality of second ports; and
supplying, in a subsequent substrate clamping, the inert gas to the region between the substrate and the substrate support through the first port.

15. The method according to claim 14, wherein in the substrate loading the inert gas is only supplied to the plurality of second ports, and/or wherein in the substrate clamping, the inert gas is only supplied to the first port, and/or wherein the supplying, in the substrate clamping, of the inert gas is performed for more than 90% of the time that the substrate is clamped to the substrate support.

16. The method according to claim 14, further comprising extracting fluid from the region between the substrate and the substrate support using a plurality of third ports radially outwards of the plurality of second ports.

17. The method according to claim 16, wherein the plurality of third ports are configured to be in fluid communication with a region of pressure that is greater than 400 mbar less than ambient pressure and less than 800 mbar less than ambient pressure.

18. The method according to claim 14, wherein the central region of the substrate support is a region in which the radial distance to the centre of the substrate support is less than 25 mm.

19. The method according to claim 14, wherein the radial distance between each of the plurality of second ports and the centre of the substrate support is more than 40 mm and less than 100 mm, and/or wherein the radial distance between each of the plurality of second ports and the centre of the substrate support is more than 13% of the diameter of the substrate and less than 33% of the diameter of the substrate.

20. The substrate holding system according to claim 1, wherein the inert gas consists essentially of nitrogen, and/or wherein the substrate support is formed of SiSiC, and/or wherein the substrate support is coated with diamond or with diamond-like carbon.
